(19) United States
(12) Patent Application Publication
(10) Pub. No.: US 2021/0249330 A1
(43) Pub. Date: Aug. 12, 2021

(54) COMPOSITE THERMAL MATRIX

(71) Applicant: Intel Corporation, Santa Clara, CA (US)

(72) Inventors: Nicholas S. Haehn, Scottsdale, AZ (US); Nicholas Neal, Gilbert, AZ (US)

(21) Appl. No.: 16/783,804

(22) Filed: Feb. 6, 2020

(51) Int. Cl. H01L 23/367; H01L 23/473; H01L 21/50

(52) U.S. Cl. CPC H01L 23/3677; H01L 21/50; H01L 23/473

(57) ABSTRACT

Embodiments herein relate to systems, techniques, and/or processes directed to a composite thermal matrix structure to provide thermal conductivity within a package. The composite thermal matrix may include a first material that is substantially solid and a second material that is liquid and absorbed into the first material. A package may include the composite thermal matrix within an integrated heat sink coupled with a printed circuit board and encapsulating one or more die where the thermal matrix structure is in a state of compressive stress within the heat sink. The thermal matrix structure may expand and contract as the heat sink warps during thermal cycling to maintain constant thermal conductivity with low stress on the package.

### FIELD

Embodiments of the present disclosure generally relate to the field of package assemblies, and in particular package assemblies that include integrated heat spreaders.

### BACKGROUND

Continued reduction in end product size of mobile electronic devices such as smart phones and ultrabooks is a driving force for the development of reduced size system in package components.

### BRIEF DESCRIPTION OF THE DRAWINGS

FIG. 1 illustrates an example of a package assembly with an integrated heat spreader (IHS) surrounding dies that are coupled with a substrate, in accordance with embodiments.

FIG. 2 illustrates an example of a composite thermal matrix, in accordance with embodiments.

FIG. 3 illustrates an example of a process to create a package with dies surrounded by an IHS that includes a composite thermal matrix, in accordance with embodiments.

FIG. 4 illustrates an example of a process to create a composite thermal matrix, in accordance with embodiments.

FIG. 5 schematically illustrates a computing device, in accordance with embodiments.

### DETAILED DESCRIPTION

Embodiments of the present disclosure may generally relate to systems, apparatus, techniques, and/or processes directed to a composite thermal matrix structure to provide thermal conductivity. Embodiments may include a housing that may be coupled with a printed circuit board (PCB), that contains one or more die and the thermal matrix structure in a state of compressive stress within the housing structure. In embodiments, the compressed thermal matrix structure may remain in contact with an inner surface of the housing during operation of the one or more die as generated heat may deform the housing. In embodiments, the housing may be an integrated heat spreader (IHS).

High-power silicon micro processing packages continue to increase power density along with performance requirements. This presents a thermal challenge, especially for stacked-die package configurations. Examples of these types of packages include high-bandwidth memory (HBM) and silicon interposers with chips attached above the interposers. In addition, thermal cycling and changes in temperatures over the life-time of the package may result in significant degradation of the thermal interface materials (TIMs), particularly towards the end of their lifecycle. This degradation may occur due to repetitive expansion and contraction of the package components caused by thermal cycling, which may result in delamination of TIMs.

In particular, the delamination of interfaces may occur between the TIM and an IHS. The delamination, or other deformation, may result in higher thermal resistance at those interfaces. In addition, multiple TIMs within a package having different coefficients of thermal expansion (CTE) mismatches may also cause package warping and package performance degradation. In some packages, there may be empty space underneath the IHS, such as an air void, that provides limited thermal conductivity and may increase package warping over time due to wider ranges of thermal cycling.

Legacy implementations may limit TIMs within packages to materials with similar CTE, so that during the thermal cycling process the interface stresses within the package are decreased, lowering the risk of structural degradation. However, these constraints may result in material selections for the TIM and package designs that are not ideal for thermal performance, because not all materials would be available. In legacy implementations only materials that fit the CTE, geometric, and mechanical requirements of the package may be used.

Implementations of embodiments described herein may significantly improve thermal performance of high-performance packages without necessitating complicated system cooling changes. From an external point of view, a package may appear the same while running cooler and having a longer lifetime due to less thermal and structural degradation due to mechanical stress induced by CTE mismatches over a series of repetitive thermal cycles. In embodiments, the mechanical compliance introduced with a composite thermal matrix affect thermal transfer without causing mechanical mismatch.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

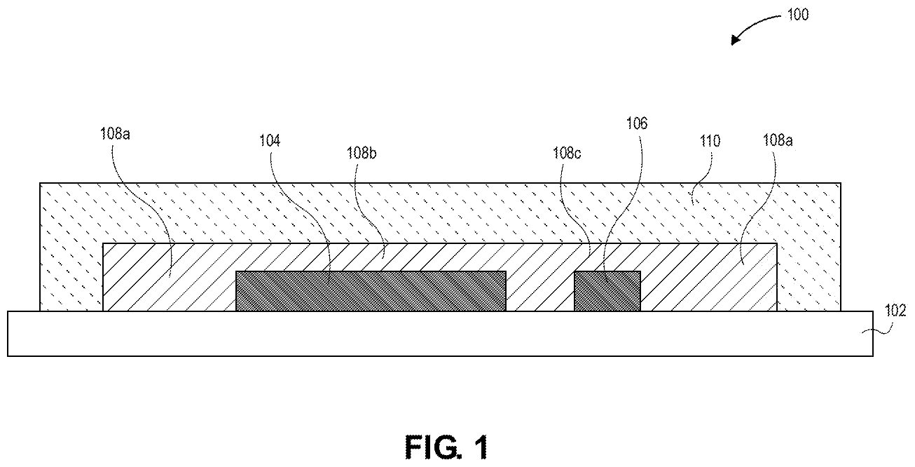

FIG. 1 illustrates an example of a package assembly with an integrated heat spreader (IHS) surrounding dies that are coupled with a substrate, in accordance with embodiments. Diagram 100 is a package that includes a first die 104, which may be a processor, and a second die 106 that may be an HBM, a graphics processor unit (GPU), or some other active component that are physically coupled with a substrate 102. In embodiments, the first die 104 and the second die 106 may be a single die, multiple dies, stacked dies, or some other combination of components that may make up a package. Surrounding the first die 104 and the second die 106 is an IHS 110. In embodiments, IHS 110 may be made of copper, nickel, aluminum or any high-conductivity metal.

In embodiments, the IHS 110 may surround the first die 104 and the second die 106. A sealed volume 108 may be formed between the IHS 110 and the substrate 102. A first region 108a may correspond to an empty space between the IHS 110 and the substrate 102. A second region 108b refers to a gap between the IHS 110 and the top surface of the first die 104 processor. In legacy implementations, in the second region 108b a first TIM material (not shown) may be placed between the first die 104 and the IHS 110. A third region 108c refers to a gap between the IHS 110 and the top surface of the second die 106. In legacy implementations, in the third region 108c a second TIM material (not shown) may be placed between IHS 110 and the top surface of the second die 106 to conduct thermal energy to the IHS 110. In legacy implementations, the first TIM and the second TIM may be of different materials with different thermal conductivity properties in different CTEs. In embodiments described herein, the sealed volume 108 may be filled with a composite thermal matrix as described below.

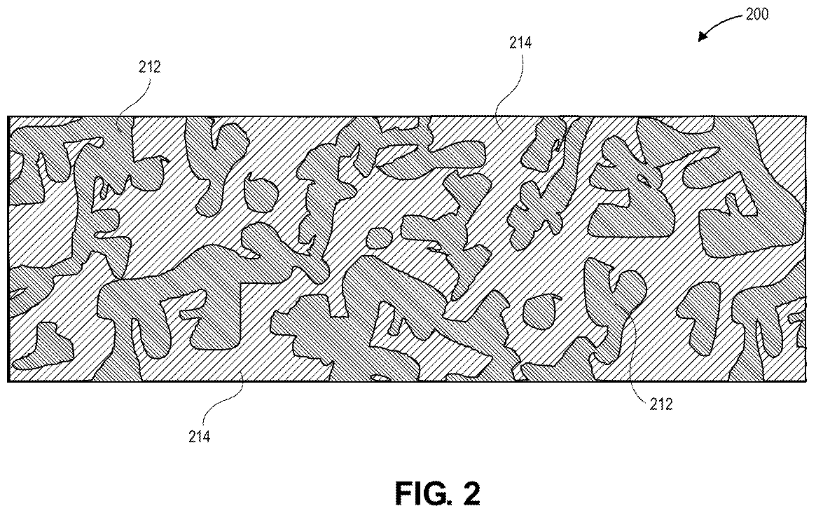

FIG. 2 illustrates an example of a composite thermal matrix, in accordance with embodiments. A composite thermal matrix 200 may be used to fill the sealed volume 108 of diagram 100. In embodiments, the composite thermal matrix 200 may adjust or expand within the sealed volume 108 to account for any warping or distortions in the IHS 110 due to thermal energy build up during package 100 operation.

In embodiments, the composite thermal matrix 200 may include two materials. The first material 212 may be referred to as a matrix carrier or a matrix structure. The second material 214 may be a high thermal conductivity liquid or a high thermal conductivity metal that undergoes a phase change from solid to liquid at defined temperature ranges. The temperature ranges may include operating temperatures of the package 100. In embodiments, the first material 212 may be a solid and flexible material to allow sufficient compliance to changing boundaries, have a high surface energy, and/or be hydrophilic. In embodiments, the first material 212 may remain solid but flexible under all operating temperatures of the package 100. In embodiments, the first material 212 may include a flexible resin (e.g. from Formlabs® or Zortrax®), polyethylene, low-density polyethylene, and/or polyvinyl chloride. In embodiments, the first material 212 may be analogous to or may have a structure and characteristics similar to a sponge material. In addition, the first material 212 may be placed in a continual state of compressive stress while placed in the volume 108 under the IHS 110 of package 100.

The second material 214 may be absorbed into the sponge-like structure of the first material 212. The second material 214 may be a liquid that stays in a liquid state throughout the operational temperature of the package 100. Examples may include, but are not limited to, bismuth, gallium, tin, indium zinc, cadmium, and/or antimony. In embodiments, the second material 214 may be a phase-change material that changes from a liquid to a metal within a range of temperatures. In embodiments, one of the temperatures may be at or near 100° C., which may correspond to an operational temperature of the package 100. The second material 214 may be liquid that has high conductivity, and wets well to the first material 212 matrix. In embodiments, the second material 214 may be a high thermal conductivity metal or liquid. In embodiments, a high thermal conductivity metal may have a characteristic of expanding when it is heated.

Turning back to FIG. 1, the composite thermal matrix 200 may be placed within the sealed volume 108, between the IHS 110, and the dies 104, 106 and substrate 102. In embodiments, the composite thermal matrix 200 will be compressed within the volume 108, and will remain in a state of compressive stress during the life of the package 100. During operation of the package 100, thermal cycling of the composite thermal matrix 200 will become compliant and will expand to fill any empty spaces that may be formed from expansion of the package 100 at higher temperatures, or shrink as external boundaries, such as the IHS 110, contract due to warping. This expansion and contraction is due to the liquid portion of the composite thermal matrix 200 either expanding or contracting as the second material 214 converts between a solid and a liquid, or by expanding because the composite thermal matrix 200 is under a compressive stress within the package 100.

In particular, sealed volume regions 108b and 108c that have a shorter distance to the IHS 110 may acquire heat faster than thicker regions 108a. In legacy implementations that may have less flexible TIMs (not shown) cracks or voids (not shown) may appear based upon temperature deformations of the IHS 110, and result in mechanical stresses on the package 100, inefficient thermal conductivity, or both. In embodiments described herein, the composite thermal matrix 200 inserted in the sealed volume 108 will allow the sealed volume regions 108b and 108c to maintain constant physical and thermal contact between the dies 104, 106 and the IHS 110 even with heat warpage, without creating cracks or voids that may be found in legacy TIMs that are less flexible.

The distance between the top of the die 104 and a surface of the IHS 110 may have a substantially consistent thickness, for example 50 p.m. However, during thermal cycling this thickness may vary due to, for example, warping of the package 100. Unlike legacy TIM materials that are less flexible, the composite thermal matrix 200 will flow into these areas of varied thickness to ensure continuity of thermal conductivity.

With respect to the composite thermal matrix 200, in embodiments it may be placed under a compressive stress at the time of insertion into a sealed volume 108. This may be done if the second material 214 of the composite thermal matrix 200 does not wet well to the first material 212 and may tend to separate after being combined unless placed under a compressive state and confined by one or more boundaries where a low thermal resistance is desired within a sealed volume 108. However, in embodiments where the second material 214 does wet well to the first material 212, during thermal cycling the second material 214 will stay in contact with the first material 212, and provide good thermal conductivity throughout the composite thermal matrix 200. In these embodiments, the composite thermal matrix 200 may not be required to be under a compressive stress or be bounded within a sealed volume.

In embodiments, the second material 214 may be a phase change material. In these embodiments, when the composite thermal matrix 200 encounters a high burst of energy, for example from a CPU 104, the phase change material will be able to absorb short duration transient temperature and convert from a metal to a liquid. The phase conversion of the second material 214 will use the latent heat of fusion to absorb additional energy.

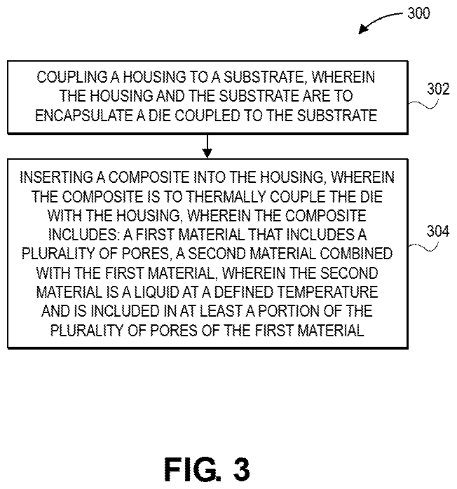

FIG. 3 illustrates an example of a process to create a package with dies surrounded by an IHS that includes a composite thermal matrix, in accordance with embodiments. Process 300 may be performed by one or more elements, techniques, or processes that may be found in FIGS. 1-2.

At block 302, the process may include coupling a housing to a substrate, wherein the housing and the substrate are to encapsulate a die coupled to the substrate. In embodiments, the housing may be similar to IHS 110, the substrate may be similar to substrate 102, and the die 104 may be similar to die 104 or die 106 of FIG. 1. In embodiments, after the housing is coupled to the substrate, a sealed volume which may be similar to sealed volume 108 of FIG. 1 may be formed. During operation, thermal energy generated by the dies 104, 106 is conducted to the IHS 110.

At block 304, the process may include inserting a composite into the housing, wherein the composite is to thermally couple the die with the housing, wherein the composite includes: a first material that includes a plurality of pores, and a second material combined with the first material, wherein the second material is a liquid at a defined temperature and is included in at least a portion of the plurality of pores of the first material. In embodiments, the composite may be similar to composite thermal matrix 200 of FIG. 2. The first material that includes a plurality of pores may be similar to first material 212, which may also be referred to as a matrix. The second material may be similar to second material 214. In embodiments, the second material may be a high thermal conductivity material that is a liquid, or is a solid that may turn into a liquid at a particular temperature or temperature range.

In embodiments, thermally coupling the die with the housing may be similar to inserting the composite thermal matrix 200 into the sealed volume 108 to thermally couple the IHS 110 with the dies 104, 106. In embodiments, this insertion may cause the composite thermal matrix 200 to be under a compressive stress and to cause the composite thermal matrix 200 to fill into any warped areas of the IHS 110 as the package 100 heats during operation.

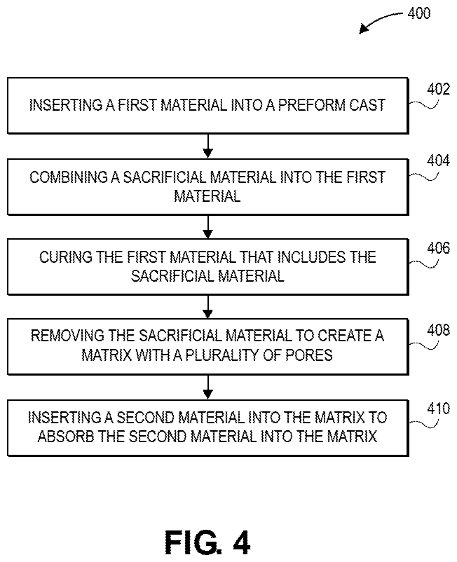

FIG. 4 illustrates an example of a process to create a composite thermal matrix, in accordance with embodiments. The process 400 may result in a composite thermal matrix 200 of FIG. 2 as described above.

At block 402, the process may include inserting a first material into a preformed cast. In embodiments, the first material may be similar to, or may be a precursor to, the first material 212 of FIG. 2. In embodiments, the preformed cast may have a shape similar to the sealed volume 108 of FIG. 1. In embodiments, the precursor to first material 212 of FIG. 2 may be a resin-based matrix carrier, which may be initially in a liquid form and poured into the preformed cast.

At block 404, the process may include combining a sacrificial material into the first material. In embodiments, the sacrificial material may include salt pellets that are suspended in the resin-based matrix carrier. In embodiments, the salt pellets may be suspended uniformly.

At block 406, the process may include curing the first material that includes the sacrificial material. In embodiments, the curing may include a heat treatment, chemical treatment, or a time-based treatment to cure the first material.

At block 408, the process may include removing the sacrificial material to create a matrix with a plurality of pores. In embodiments, the sacrificial material may be removed by a chemical treatment or by cleaning. For example, if the sacrificial material includes salt pellets it may be dissolved away in a water bath. Once the sacrificial material is removed, the first material 212 of FIG. 2 will be a matrix that include pores, similar to pores and a sponge, where the sacrificial material used to be. These pores in the matrix will later be used for absorption of liquid.

In embodiments, at this stage the first material 212 of FIG. 2 may undergo processes to improve the wetting of the services of the first material 212 to aid in absorption. For example, these processes may include, but are not limited to, plasma cleaning and liquid coating.

At block 410, the process may include inserting a second material into the matrix to absorb the second material into the matrix. The second material may be similar to second material 214 of FIG. 2. In embodiments, the first material 212 may be immersed in a vat of second material 214 to create the thermal composite matrix 200 of FIG. 2.

It should be noted that the amount of sacrificial material, the density of the material, and the placement of the material may be used to tune various thermal and mechanical properties of the resulting thermal composite matrix 200 of FIG. 2. For example, a low volume of sacrificial material would result in a composite with a higher ratio of material 212 of FIG. 2 thereby increasing the composite material structural rigidity while decreasing the composite material thermal conductivity. For a higher volume of sacrificial material, the resulting matrix would result in a higher ratio of material 214 of FIG. 2, resulting in an increased thermal conductivity of the composite.

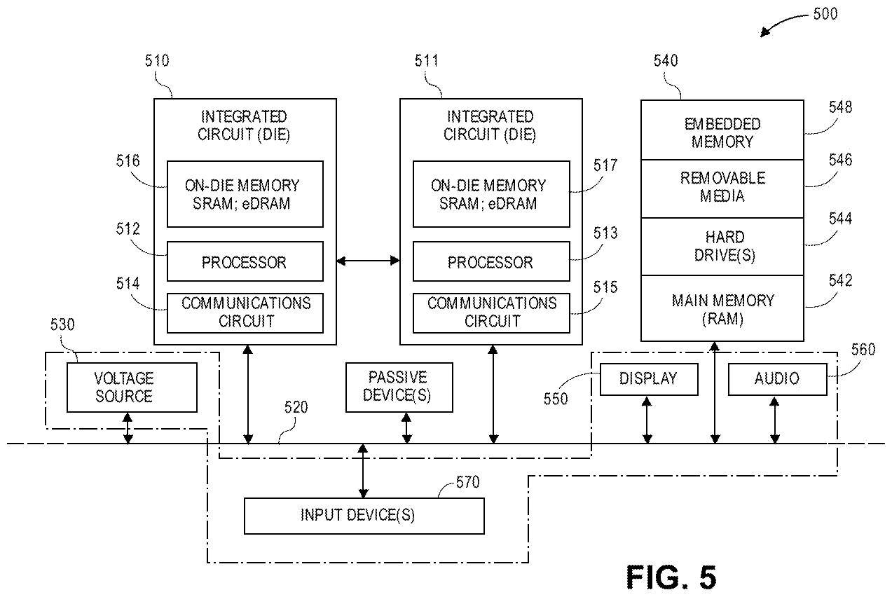

FIG. 5 schematically illustrates a computing device, in accordance with embodiments.

The computer system 500 (also referred to as the electronic system 500) as depicted can embody a composite thermal matrix, according to any of the several disclosed embodiments and their equivalents as set forth in this disclosure. The computer system 500 may be a mobile device such as a netbook computer. The computer system 500 may be a mobile device such as a wireless smart phone. The computer system 500 may be a desktop computer. The computer system 500 may be a hand-held reader. The computer system 500 may be a server system. The computer system 500 may be a supercomputer or high-performance computing system.

In an embodiment, the electronic system 500 is a computer system that includes a system bus 520 to electrically couple the various components of the electronic system 500. The system bus 520 is a single bus or any combination of busses according to various embodiments. The electronic system 500 includes a voltage source 530 that provides power to the integrated circuit 510. In some embodiments, the voltage source 530 supplies current to the integrated circuit 510 through the system bus 520.

The integrated circuit 510 is electrically coupled to the system bus 520 and includes any circuit, or combination of circuits according to an embodiment. In an embodiment, the integrated circuit 510 includes a processor 512 that can be of any type. As used herein, the processor 512 may mean any type of circuit such as, but not limited to, a microprocessor, a microcontroller, a graphics processor, a digital signal processor, or another processor. In an embodiment, the processor 512 includes, or is coupled with, a composite thermal matrix, as disclosed herein. In an embodiment, SRAM embodiments are found in memory caches of the processor. Other types of circuits that can be included in the integrated circuit 510 are a custom circuit or an application-specific integrated circuit (ASIC), such as a communications circuit 514 for use in wireless devices such as cellular telephones, smart phones, pagers, portable computers, two-way radios, and similar electronic systems, or a communications circuit for servers. In an embodiment, the integrated circuit 510 includes on-die memory 516 such as static random-access memory (SRAM). In an embodiment, the integrated circuit 510 includes embedded on-die memory 516 such as embedded dynamic random-access memory (eDRAM).

In an embodiment, the integrated circuit 510 is complemented with a subsequent integrated circuit 511. Useful embodiments include a dual processor 513 and a dual communications circuit 515 and dual on-die memory 517 such as SRAM. In an embodiment, the dual integrated circuit 510 includes embedded on-die memory 517 such as eDRAM.

In an embodiment, the electronic system 500 also includes an external memory 540 that in turn may include one or more memory elements suitable to the particular application, such as a main memory 542 in the form of RAM, one or more hard drives 544, and/or one or more drives that handle removable media 546, such as diskettes, compact disks (CDs), digital variable disks (DVDs), flash memory drives, and other removable media known in the art. The external memory 540 may also be embedded memory 548 such as the first die in a die stack, according to an embodiment.

In an embodiment, the electronic system 500 also includes a display device 550, an audio output 560. In an embodiment, the electronic system 500 includes an input device such as a controller 570 that may be a keyboard, mouse, trackball, game controller, microphone, voice-recognition device, or any other input device that inputs information into the electronic system 500. In an embodiment, an input device 570 is a camera. In an embodiment, an input device 570 is a digital sound recorder. In an embodiment, an input device 570 is a camera and a digital sound recorder.

As shown herein, the integrated circuit 510 can be implemented in a number of different embodiments, including a package substrate having a composite thermal matrix, according to any of the several disclosed embodiments and their equivalents, an electronic system, a computer system, one or more methods of fabricating an integrated circuit, and one or more methods of fabricating an electronic assembly that includes a composite thermal matrix, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed packages with a composite thermal matrix embodiments and their equivalents. A foundation substrate may be included, as represented by the dashed line of FIG. 5. Passive devices may also be included, as is also depicted in FIG. 5.

### EXAMPLES

Example 1 is an apparatus comprising: a first material that includes a substantially solid material with a plurality of pores; a second material combined with the first material; wherein the second material is included in at least a portion of the plurality of pores of the first material; and wherein the combined first material and the second material are to provide thermal energy transfer.

Example 2 may include the apparatus of example 1, wherein the second material is a liquid and wherein the second material is absorbed into the first material.

Example 3 may include the apparatus of example 1, wherein the second material undergoes a phase change from a liquid to a solid within a range of temperature values.

Example 4 may include the apparatus of example 1, wherein the second material expands based upon an increase in temperature.

Example 5 may include the apparatus of any one of examples 1-4, further comprising: a housing structure, wherein the combined first and second materials are disposed within the housing structure and are in contact with an inner surface of the housing structure; wherein the combined first and second materials are in a state of compressive stress within the housing structure; and wherein the combined first and second materials remain in contact with the inner surface of the housing structure when the housing structure is deformed.

Example 6 may include the apparatus of example 5, wherein the housing structure is deformed by heating of the housing structure.

Example 7 include the apparatus of example 5, wherein the combined first and second materials displace air voids within the structure.

Example 8 is a package comprising: a substrate; a die coupled with the substrate; a housing coupled with the substrate and surrounding the die, wherein the substrate and housing encapsulate the die; a composite within the housing to thermally couple the die with the housing, the composite comprising: a first material that includes a plurality of pores; a second material combined with the first material; wherein the second material is included in at least a portion of the plurality of pores of the first material.

Example 9 includes the package of example 8, further comprising: wherein the combined first and second materials displace air voids within the housing.

Example 10 includes the package of example 8, wherein the composite is in a state of compressive stress within the housing; and wherein the combined first and second materials remain in contact with an inner surface of the housing when the housing is deformed.

Example 11 includes the package of any one of examples 8-10, wherein the second material is a liquid and wherein the second material is absorbed into the first material.

Example 12 includes the package of any one of examples 8-10, wherein the second material undergoes a phase change from a liquid to a solid within a range of temperature values.

Example 13 includes the package of any one of examples 8-10, wherein the second material expands based upon an increase in temperature.

Example 14 includes the package of any one of examples 8-10, wherein the housing structure is deformed by heating of the housing structure.

Example 15 includes the package of any one of examples 8-10, wherein the combined first and second materials displace air voids within the structure.

Example 16 is a method for cooling a die, comprising: coupling a housing to a substrate, wherein the housing and the substrate are to encapsulate a die coupled to the substrate; inserting a composite into the housing, wherein the composite is to thermally couple the die with the housing; and wherein the composite includes: a first material that includes a plurality of pores; a second material combined with the first material, wherein the second material is a liquid at a defined temperature and is included in at least a portion of the plurality of pores of the first material.

Example 17 includes the method of example 16, wherein the second material is a solidus or liquidus material.

Example 18 includes the method of any one of examples 16-17, wherein inserting the composite into the housing further includes inserting the composite into the housing so that the composite is in a state of compressive stress within the housing.

Example 19 is a method making a thermal composite, comprising: inserting a first material into a preform cast; combining a sacrificial material into the first material; curing the first material that includes the sacrificial material; removing the sacrificial material to create a matrix with a plurality of pores; and inserting a second material into the matrix to absorb the second material into the matrix.

Example 20 includes the method of example 19, wherein the first material is a resin, the sacrificial material is salt pellets, or the second material is a solidus or liquidus material.

The above paragraphs describe examples of various embodiments.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

What is claimed is:

1. An apparatus comprising:
a first material that includes a substantially solid material with a plurality of pores;
a second material combined with the first material;
wherein the second material is included in at least a portion of the plurality of pores of the first material; and
wherein the combined first material and the second material are to provide thermal energy transfer.

2. The apparatus of claim 1, wherein the second material is a liquid and wherein the second material is absorbed into the first material.

3. The apparatus of claim 1, wherein the second material undergoes a phase change from a liquid to a solid within a range of temperature values.

4. The apparatus of claim 1, wherein the second material expands based upon an increase in temperature.

5. The apparatus of claim 1, further comprising:
a housing structure, wherein the combined first and second materials are disposed within the housing structure and are in contact with an inner surface of the housing structure;
wherein the combined first and second materials are in a state of compressive stress within the housing structure; and
wherein the combined first and second materials remain in contact with the inner surface of the housing structure when the housing structure is deformed.

6. The apparatus of claim 5, wherein the housing structure is deformed by heating of the housing structure.

7. The apparatus of claim 5, wherein the combined first and second materials displace air voids within the structure.

8. A package comprising:
a substrate;
a die coupled with the substrate;
a housing coupled with the substrate and surrounding the die, wherein the substrate and housing encapsulate the die;
a composite within the housing to thermally couple the die with the housing, the composite comprising:
a first material that includes a plurality of pores;
a second material combined with the first material;
wherein the second material is included in at least a portion of the plurality of pores of the first material.

9. The package of claim 8, further comprising: wherein the combined first and second materials displace air voids within the housing.

10. The package of claim 8,
wherein the composite is in a state of compressive stress within the housing; and
wherein the combined first and second materials remain in contact with an inner surface of the housing when the housing is deformed.

11. The package of claim 8, wherein the second material is a liquid and wherein the second material is absorbed into the first material.

12. The package of claim 8, wherein the second material undergoes a phase change from a liquid to a solid within a range of temperature values.

13. The package of claim 8, wherein the second material expands based upon an increase in temperature.

14. The package of claim 8, wherein the housing structure is deformed by heating of the housing structure.

15. The package of claim 8, wherein the combined first and second materials displace air voids within the structure.

16. A method for cooling a die, comprising:
coupling a housing to a substrate, wherein the housing and the substrate are to encapsulate a die coupled to the substrate;
inserting a composite into the housing, wherein the composite is to thermally couple the die with the housing; and
wherein the composite includes:
a first material that includes a plurality of pores;
a second material combined with the first material, wherein the second material is a liquid at a defined temperature and is included in at least a portion of the plurality of pores of the first material.

17. The method of claim 16, wherein the second material is a solidus or liquidus material.

18. The method of claim 16, wherein inserting the composite into the housing further includes inserting the composite into the housing so that the composite is in a state of compressive stress within the housing.

19. A method making a thermal composite, comprising:
inserting a first material into a preform cast;
combining a sacrificial material into the first material;
curing the first material that includes the sacrificial material;
removing the sacrificial material to create a matrix with a plurality of pores; and
inserting a second material into the matrix to absorb the second material into the matrix.

20. The method of claim 19, wherein the first material is a resin, the sacrificial material is salt pellets, or the second material is a solidus or liquidus material.
